(19) United States
(12) Patent Application Publication
(10) Pub. No.: US 2007/0108971 A1
(43) Pub. Date: May 17, 2007

(54) Eddy current inspection of materials

(76) Inventors: Irving I. Dardik, Califon, NJ (US); Raymond G. Thompson, Birmingham, AL (US)

Correspondence Address: FISH & NEAVE IP GROUP;ROPES & GRAY LLP, 1211 AVENUE OF THE AMERICAS, NEW YORK, NY, 10036-8704, US

(21) Appl. No.: 10/573,299

(22) PCT Filed: Sep. 22, 2004
(86) PCT No.: PCT/US04/31134

§ 371 Date: Jan. 8, 2007

Related U.S. Application Data
(60) Provisional application No. 60/505,047, filed on Sep. 22, 2003.

(51) Int. Cl. G01R 33/12

(52) U.S. Cl. 324/239

(57) ABSTRACT

Methods and apparatus for eddy current inspection are provided. Eddy current inspection is used in a variety of industries to find defects and make measurements and inspections of various materials. Providing superwaves as the excitation current and/or voltage signal for eddy current inspection may produce higher intensity and lower signal-to-noise eddy currents than in typical eddy current inspection. This will result in faster and more accurate inspections. Eddy current inspection using superwaves, in accordance with the invention, may also enhance the ability to detect small defects in difficult to inspect materials and configurations.

This application claims the benefit of U.S. provisional patent application No. 60/505,047, filed Sep. 22, 2003, which is hereby incorporated by reference herein in its entirety.

### BACKGROUND OF THE INVENTION

This invention relates generally to eddy current inspection. Eddy current inspection is used in a variety of industries to find defects and make measurements and inspections of various materials.

One of the primary uses of eddy current inspection is for defect detection when the nature of the possible defect is well understood. In general, the technique is used to inspect a relatively small area. The probe design and test parameters must be established with a good understanding of the flaw that is to be detected. Since eddy currents tend to concentrate at the surface of a material, eddy current inspection is generally used to detect surface and near surface defects.

In thin materials such as tubing and sheet stock, eddy currents can be used to measure the thickness of the material. This makes eddy current a useful tool for detecting corrosion and other types of damage that cause a thinning of the material. For example, this technique is used to make corrosion thinning measurements on aircraft skins and in the walls of tubing used in assemblies such as heat exchangers. Eddy current testing is also used to measure the thickness of paints and other coatings.

Eddy currents are also affected by the electrical conductivity and magnetic permeability of materials. Therefore, eddy current measurements can be used to sort materials and to tell if a material has seen high temperatures or has been heat treated, which changes the conductivity of some materials.

Eddy current equipment and probes can be purchased in a wide variety of configurations. Eddyscopes and a conductivity tester may come packaged in very small and battery operated units for easy portability. Computer based systems are also available that provide easy data manipulation features for the laboratory. Signal processing software has also been developed for trend removal, background subtraction, and noise reduction. Impedance analyzers are also sometimes used to allow improved quantitative eddy-current measurements. Some laboratories have multidimensional scanning capability that is used to produce images of the scan regions. A few portable scanning systems also exist for special applications such as scanning regions of aircraft fuselage.

Present day eddy current inspection does not provide the ability to detect small defects in difficult to inspect materials and configurations. It is desirable for eddy current inspection that result in faster and more accurate inspections and that produce eddy currents with higher intensity and lower signal- to-noise ratios than currently available. Further improvements in eddy current inspection are also desirable.

### SUMMARY OF THE INVENTION

It is therefore an object of the present invention to apply electrical pulses in a predetermined pattern (i.e., superwaves) as the excitation current and/or voltage signal for eddy current inspection.

A significant feature of the present invention which distinguishes it from prior inspection techniques in which the excitation current for the eddy current inspection is pulsed, is that in accordance with the invention, pulsing takes place in a pulse pattern that heightens the intensity and lowers the signal-to-noise ratio of eddy currents and, hence, improves the ability to detect smaller defects in difficult to inspect materials and configurations.

In one embodiment of the invention, a train of voltage or current pulse packets is applied as the excitation signal for eddy current inspection. Each of the packets is comprised of a cluster of pulses. The amplitude and duration (or alternatively, frequency) of each pulse in the packet, the duration of the intervals between pulses, and the duration of the intervals between successive packets in the train are in a predetermined pattern in accordance with “superwaving” waves, in which each wave is modulated by waves of different amplitude and duration.

It is also an object of the present invention to emit magnetic fields or to induce eddy currents which correspond to or are substantially similar to the form of superwaves.

### BRIEF DESCRIPTION OF THE DRAWINGS

The above and other advantages of the invention will be more apparent upon consideration of the following detailed description, taken in conjunction with the accompanying drawings, in which like reference characters refer to like parts throughout, and in which:

FIG. 1 illustrates a typical electromagnetic induction circuit used for eddy current testing;

FIG. 2A illustrates a graph of a typical square wave input to an electromagnetic induction circuit;

FIG. 2B illustrates a graph of the current flowing through an inductor coil receiving the square wave input;

FIGS. 3 and 3A schematically illustrate superwaving wave phenomena;

FIG. 4 schematically illustrates the magnetic fields emitted from an electromagnetic induction circuit and the eddy currents induced in the inspected material; and

FIG. 5 schematically illustrates the depth of penetration of eddy currents in the inspected material.

### DETAILED DESCRIPTION OF THE INVENTION

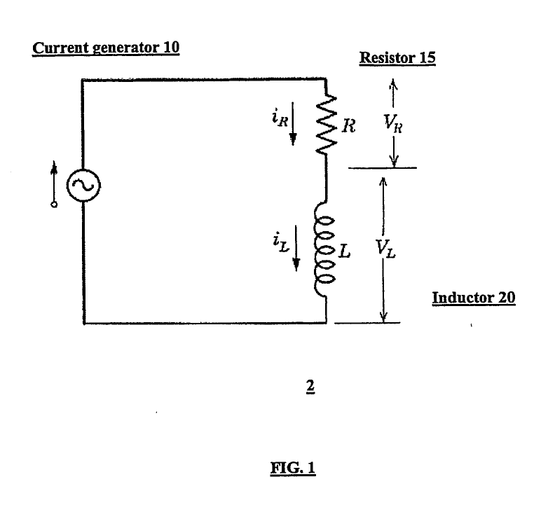

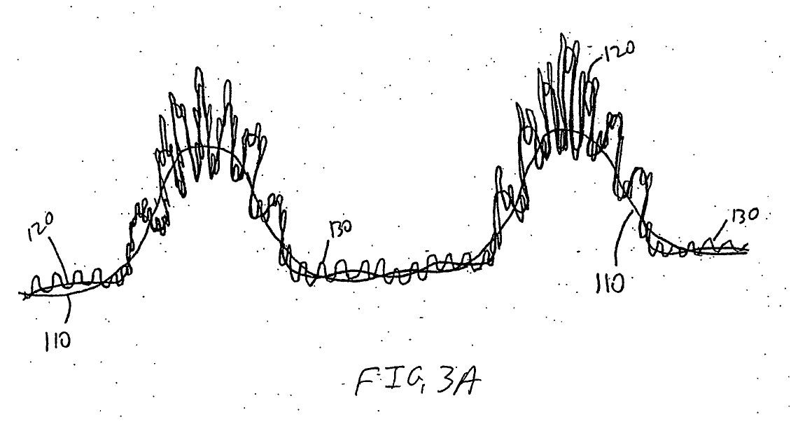

Conventional eddy current inspection may use an alternating current electrical signal to generate a magnetic field from an induction coil. FIG. 1 illustrates a typical electromagnetic induction circuit 2. Current generator 10 generates an alternating current in electromagnetic induction circuit 2. The current flows through resistor 15 and inductor 20. Inductor 20, may be, for example, a coil of wire. An induced magnetic field radiates from inductor 20. The properties of the magnetic field, such as the intensity, frequency, and orientation may be related to the current generated by current generator 10. In accordance with one embodiment of the present invention, current generator 10 generates current having substantially a superwave pulse pattern (as described herein below with respect to FIGS. 3 and 3A).

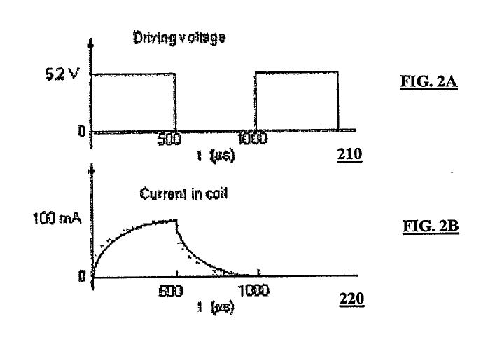

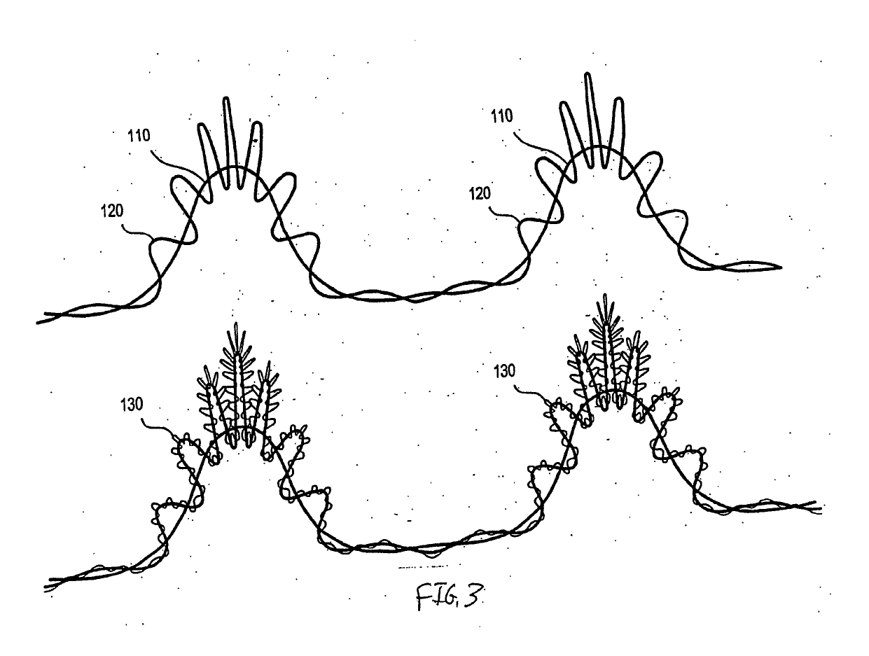

Typically sinusoidal or square waveforms are generated by current generator 10 in electromagnetic induction circuit 2. FIG. 2A shows illustrative graph 210 of a typical square waveform and FIG. 2B shows illustrative graph 220 of the current flowing through inductor 20 when the square waveform of FIG. 2A is input to induction circuit 2. In accordance with the invention, superwaves may be generated by current generator 10 and input to induction circuit 2 instead of typical sinusoidal and square waveforms.

The “superwaves” pulse pattern is in accordance with superwaving activity as set forth in the theory advanced in the Irving I. Dardik article “The Great Law of the Universe” that appeared in the March/April 1994 issue of the “Cycles” Journal. This article is incorporated herein by reference.

As pointed out in the Dardik article, it is generally accepted in science that all things in nature are composed of atoms that move around in perpetual motion, the atoms attracting each other when they are a little distance apart and repelling upon being squeezed into one another. In contradistinction, the Dardik hypothesis is that all things in the universe are composed of waves that wave, this activity being referred to as “superwaving.” Superwaving gives rise to and is matter in motion (i.e., both change simultaneously to define matter-space-time).

Thus in nature, changes in the frequency and amplitude of a wave are not independent and different from one another, but are concurrently one and the same, representing two different hierarchical levels simultaneously. Any increase in wave frequency at the same time creates a new wave pattern, for all waves incorporate therein smaller waves and varying frequencies, and one cannot exist without the other.

Every wave necessarily incorporates smaller waves, and is contained by larger waves. Thus each high-amplitude low-frequency major wave is modulated by many higher frequency low-amplitude minor waves. Superwaving is an ongoing process of waves waving within one another.

FIG. 3 (adapted from the illustrations in the Dardik article) schematically illustrates superwaving wave phenomena. FIG. 3 illustrates low-frequency major wave 110 modulated, for example, by minor waves 120 and 130. Minor waves 120 and 130 have progressively higher frequencies (compared to major wave 110). Other minor waves of even higher frequency may modulate major wave 110, but are not shown for clarity. This same superwaving wave phenomena is depicted in the time-domain in FIG. 3A.

This superwaving principle of waves waving demonstrates that wave frequency and wave intensity (amplitude squared) are simultaneous and continuous. The two different kinds of energy (i.e., energy carried by the waves that is proportional to their frequency, and energy proportional to their intensity) are also simultaneous and continuous. Energy therefore is waves waving, or “wave/energy.” In accordance with the invention, the superwaving wave activity may be used to generate magnetic flux in a coil for enhanced eddy current inspection.

When an alternating electrical current is fed through an inductor, it produces a magnetic field around the inductor that expands as the alternating current rises to maximum and collapses as the current is reduced to zero. If another electrical conductor, such as a conducting surface to be inspected, is brought into close proximity with the changing magnetic field, eddy currents will be induced in this second conductor. Eddy currents are induced electrical currents that flow in a substantially circular path. By detecting and measuring the eddy currents in the conducting surface, defects and other properties of the conducting surface may be detected.

The inductor or other suitable magnetic field generator and detector is incorporated into a probe that may be used for eddy current inspection. Several different inductor probes are commonly known and may be used for each of the different applications of eddy current inspection previously described. Further, the type of inductor probe used may be based on the material and defect to be inspected. Products for the various types of eddy current testing of components may be manufactured by ibg NDT Systems Corporation of Farmington Hills, Mich. and Zetec, Inc. of Issaquah, Wash., for example.

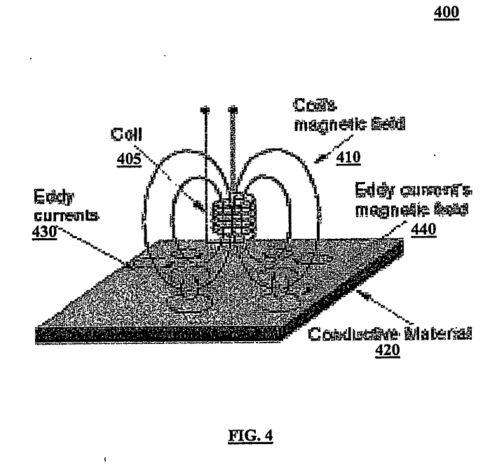

FIG. 4 illustrates the operation of an inductor probe 400 with coil 405 for eddy current inspection. The inductor probe 400 emits a magnetic field 410 which penetrates the surface of the material 420 to be inspected. The magnetic field 410 induces electrical eddy currents 430 near the surface of the material 420 being inspected. Properties of the material 420 may be detected by measuring these eddy currents 430. In particular, the eddy currents 430 generate eddy current magnetic fields 440 which may be detected and measured by the inductor probe 400.

Using superwaves for eddy current inspection instead of conventional square or sinusoidal waveforms, preferably creates greater turbulence in the material 420 to be inspected, and therefore, increases and intensifies the production of eddy currents 430. The increased and intensified eddy currents 430 preferably provide more information about the probed material 420 than would be provided by conventional eddy current inspection techniques.

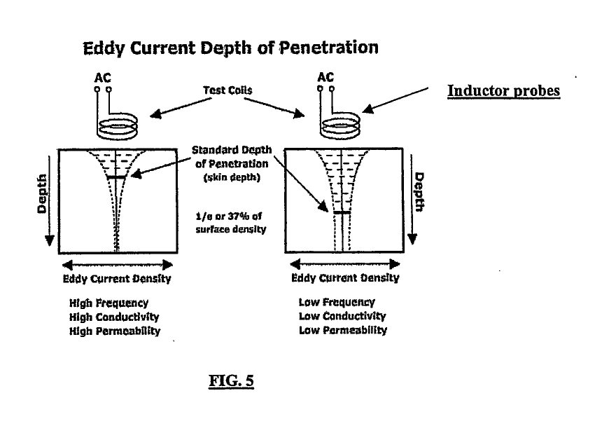

FIG. 5 schematically illustrates the depth of penetration of eddy currents in the inspected material. As may be seen in FIG. 5, the eddy currents preferably penetrate the surface to varying depths depending on the material being inspected and the frequency of the signal in the eddy current electrical circuit.

Eddy current inspection can be used for a variety of inspection applications as discussed in the introduction and as detailed in the following ASTM inspection standards.

British Standards (BS) and American Standards (ASTM) relating to magnetic flux leakage and eddy current methods of testing are given below. National standards are currently being harmonized across the whole of Europe, and British Standards are no exception. Harmonized standards will eventually be identified by the initials BS EN; for example, BS 5411 has been revised and is now known as BS EN 2360. The year of updating a British Standard is given in brackets. ASTM standards are published annually and updated when necessary.

British Standards (BS):

BS 3683 (part 5):1965 (1989)—Eddy current flaw detection glossary;

BS 3889 (part 2A): 1986 (1991)—Automatic eddy current testing of wrought steel tubes;

BS 3889 (part 213): 1966 (1987)—Eddy current testing of nonferrous tubes; and

BS 5411 (part 3):1984—Eddy current methods for measurement of coating thickness of nonconductive coatings on nonmagnetic base material. Withdrawn: now known as BS EN 2360 (1995).

American Society for Testing and Materials (ASTM):

ASTM A 450/A450M —General requirements for carbon, ferritic alloys and austenitic alloy steel tubes;

ASTM B 244—Method for measurement of thickness of anodic coatings of aluminum and other nonconductive coatings on nonmagnetic base materials with eddy current instruments;

ASTM B 659—Recommended practice for measurement of thickness of metallic coatings on nonmetallic substrates;

ASTM E 215—Standardizing equipment for electromagnetic testing of seamless aluminum alloy tube;

ASTM E 243—Electromagnetic (eddy current) testing of seamless copper and copper alloy tubes;

ASTM E 309—Eddy current examination of steel tubular products using magnetic saturation;

ASTM E 376—Measuring coating thickness by magnetic field or eddy current (electromagnetic) test methods;

ASTM E 426—Electromagnetic (eddy current) testing of seamless and welded tubular products austenitic stainless steel and similar alloys;

ASTM E 566—Electromagnetic (eddy current) sorting of ferrous metals;

ASTM E 571—Electromagnetic (eddy current) examination of nickel and nickel alloy tubular products

ASTM E 690—In-situ electromagnetic (eddy current) examination of nonmagnetic heat-exchanger tubes;

ASTM E 703—Electromagnetic (eddy current) sorting of nonferrous metals;

ASTM E 1004—Electromagnetic (eddy current) measurements of electrical conductivity;

ASTM E 1033—Electromagnetic (eddy current) examination of type F continuously welded (CW) ferromagnetic pipe and tubing above the Curie temperature;

ASTM E 1316—Definition of terms relating to electromagnetic testing; and

ASTM G 46 Recommended practice for examination and evaluation of pitting corrosion.

One skilled in the art will appreciate that the present invention can be practiced by other than the described embodiments, which are presented for purposes of illustration and not of limitation, and the present invention is only limited by the claims which follow.

What is claimed is:

1. An apparatus for eddy current inspection, the apparatus comprising:
an induction probe having an input operative to receive a train of pulsed electrical packets, a cluster of pulses being superimposed on each packet; and
wherein each pulse in the cluster of pulses has an amplitude that is proportional to an instantaneous amplitude of a major wave associated with the train of pulsed electrical packets, and wherein each pulse in the cluster of pulses has a frequency that is proportional to an instantaneous frequency of the major wave associated with the train of pulsed electrical packets.

2. An apparatus for eddy current inspection, the apparatus comprising:
an induction probe operative to emit a magnetic field corresponding to a train of pulsed packets, a cluster of pulses being superimposed on each packet; and
wherein each pulse in the cluster of pulses has an amplitude that is proportional to an instantaneous amplitude of a major wave associated with the train of pulsed packets, and wherein each pulse in the cluster of pulses has a frequency that is proportional to an instantaneous frequency of the major wave associated with the train of pulsed packets.

3. A method for eddy current inspection, the method comprising:
generating a train of pulsed electrical packets, a cluster of pulses being superimposed on each packet, wherein each pulse in the cluster of pulses has an amplitude that is proportional to an instantaneous amplitude of a major wave associated with the train of pulsed electrical packets, and wherein each pulse in the cluster of pulses has a frequency that is proportional to an instantaneous frequency of the major wave associated with the train of pulsed electrical packets;
inputting the train of pulsed electrical packets to an electromagnetic induction circuit, the electromagnetic induction circuit emitting a magnetic field in response to the inputting;
using the magnetic fields to induce eddy currents in a material; and
detecting the eddy currents in the material.

4. A method for eddy current inspection, the method comprising:
generating a magnetic field corresponding to a train of pulsed packets, a cluster of pulses being superimposed on each packet, wherein each pulse in the cluster of pulses has an amplitude that is proportional to an instantaneous amplitude of a major wave associated with the train of pulsed electrical packets, and wherein each pulse in the cluster of pulses has a frequency that is proportional to an instantaneous frequency of the major wave associated with the train of pulsed packets;
using the magnetic fields to induce eddy currents in a material; and
detecting the eddy currents in the material.
